(19) United States
(12) Patent Application Publication
(10) Pub. No.: US 2015/0375253 A1
(43) Pub. Date: Dec. 31, 2015

(54) DEVICE FOR WET-TREATING THE LOWER FACE OF SUBSTRATES

(71) Applicant: GEBR. SCHMID GMBH, Freudenstadt (DE)

(72) Inventors: Philip MÜCK, Freudenstadt (DE); Michael NIETHAMMER, Claw (DE); Kai WEISSER, Villingen-Schwenningen (DE)

(21) Appl. No.: 14/765,231

(22) PCT Filed: Jan. 23, 2014
(86) PCT No.: PCT/EP2014/051319

§ 371 Date: Jul. 31, 2015

(30) Foreign Application Priority Data
Feb. 8, 2013 (DE) 10 2013 202 138.0

(51) Int. Cl. B05C 1/08; H05K 3/06; B05C 1/02

(52) U.S. Cl. CPC B05C 1/0821; B05C 1/025; H05K 3/06

(57) ABSTRACT

A device for the wet treatment of flat substrates (S1, S2) by wetting the underside with fluid, wherein the device contains at least one wetting station (BA, BB) with at least one wetting roll (WA, WB) for wetting the underside of the substrates to be treated and moved in a transporting direction (TR) over the treatment roller with fluid, and also a roller transport system which has a plurality of transport rollers (T1 to T7, WA, WB), arranged one after another in a spaced apart manner in the transporting direction, including the at least one wetting roll, for transporting the substrates to be treated and resting on the transport rollers in the transporting direction. Furthermore, the invention relates to the use of such a device for the wet treatment of substrates. The wetting roll is arranged at a height (Hm) which is higher by a predetermined height offset (ΔHA) than a height (Hu) which is defined by a section, adjoining the supply side of the wetting roll, of the roller transport system.

The invention relates to a device for the wet treatment of flat substrates by wetting the underside with fluid, wherein the device contains at least one wetting station with at least one wetting roll for wetting the underside of the substrates to be treated and moved in a transporting direction over the treatment roller with fluid, and also a roller transport system which has a plurality of transport rollers, arranged one after another in a spaced apart manner in the transporting direction, including the at least one wetting roll, for transporting the substrates to be treated and resting on the transport rollers in the transporting direction. Furthermore, the invention relates to a use of such a device for the wet treatment of substrates.

Devices of this type are known, as are provided for example by the applicant and are described in the applicant's earlier German Patent Application DE 10 2011 081 981, by way of which substrates can be treated in a continuous process and which contain a plurality of wetting stations, arranged one after another in a spaced apart manner in the transporting direction, each having one or more wetting rolls. A roller transport system ensures horizontal transport of the substrates to be wetted on the underside from one wetting station to the next and over the respective wetting station. To this end, the roller transport system contains a plurality of transport rollers, arranged one after another in a spaced apart manner in a horizontal transporting direction, on which the substrates rest and to which the wetting rolls also belong. The transport rollers, including the wetting rolls, of all the wetting stations rest, in these conventional devices, with their top side at a uniform height, such that the substrates are always moved over the respective wetting station and from one wetting station to the next in a manner lying horizontally in a horizontal plane. The wetting rolls dip into a treatment fluid bath with a bottom part of their circumferential surface and convey the treatment fluid up to the underside of the substrate by way of their rotating circumferential surface.

Further devices for the wet treatment of flat substrates by wetting the underside with fluid are disclosed in the laid-open specifications DE 10 2005 062 527 A1 and DE 10 2005 062 528 A1, wherein the devices in said documents have a plurality of wetting rolls arranged one after another in a horizontal substrate transporting direction, a common wetting fluid tank being assigned to said wetting rolls. Here, too, all of the wetting rolls and also transport rollers, arranged outside the wetting fluid tank, of an associated continuous roller transport system are all located at one and the same height, such that the substrates to be treated are transported in a horizontal plane to the wetting fluid bath and over the wetting rolls, i.e. in a manner resting on the rotating wetting rolls.

The laid-open specification DE 101 28 386 A1 discloses a roller transport system as can be used for example in devices for the treatment of circuit boards in chemical baths. The roller transport system shown in said document has a specific arrangement for mounting the transport rollers in question. This mounting comprises a pair of lateral longitudinal members having U-shaped recesses for the respective transport roller. Special inserts are introduced into the recesses, the inner boundary walls of said inserts acting as roller bearings.

Devices of the type mentioned at the outset for the wet treatment of substrates are used for example to etch the underside of the flat substrates and usually also the lateral edges, i.e. the longitudinal and/or transverse lateral edges, thereof. To this end, with the aid of the wetting stations, they are wetted on the underside and optionally peripherally with a suitable etching solution as wetting fluid. For example, silicon wafers, which are used for the production of solar cells, may be etched in this way. In this case, it is observed that in some cases inhomogeneous etching occurs, specifically greater etching erosion in a rear wafer region in the transporting direction. If the etching process serves for the edge isolation of the solar cell wafer, this means greater edge isolation at the rear edge compared with the front edge. In order to achieve a more uniform etching result, it would be conceivable in principle to rotate the wafer through 180° about its vertical axis after for example half the treatment section and thus to transpose the front and rear edges of the wafer, and to continue the rest of the etching process in this wafer position. However, this would require a corresponding rotation station.

The technical problem underlying the invention resides in the provision of a device of the type mentioned at the outset for the wet treatment of substrates, by way of which comparatively uniform wetting of the underside with fluid is achievable with relatively little effort, such that, for example in the case of an etching process, comparatively uniform etching erosion is achieved in a front edge region and in a rear edge region of the etched substrates. A further aim of the invention is to provide an advantageous use of such a device.

The invention solves this problem by the provision of a device for the wet treatment of substrates having the features of claim 1 and a use having the features of claim 7. Advantageous developments of the invention are given in the dependent claims.

In the device according to the invention, at least one wetting roll is arranged at a height which is higher by a predetermined height offset than a height which is defined by a section, adjoining the supply side of the wetting roll, of the roller transport system. This has the result that the substrates to be treated reach the wetting roll at a lower height than the height thereof and consequently butt or run with their front edge against the wetting roll in order then to be raised thereby to the level thereof and to be transported further thereby with the substrate underside resting thereon.

Tests have revealed that in this way the wetting with fluid can be improved to an unexpectedly high degree in the front substrate region and specifically also at the substrate front edge. Thus, the abovementioned non-uniformities between the smaller degree of wetting in the front edge region and greater degree of wetting in the rear edge region of the treated substrates, as are observed in the case of the abovementioned wafer edge isolation, can be completely or at least partially compensated. In the case of the abovementioned wet etching of the underside of solar cell wafers, this means that the wafers can be etched very homogeneously by the use according to the invention of the device. The use according to the invention of the device allows in particular uniform edge isolation of the front edge and rear edge of the silicon wafers that are wet-chemically etched on the underside, without the abovementioned use of a rotation station for rotating the wafers after a first part of the etching process. Further advantageous uses reside for example in etching the underside of circuit boards and in a rinse treatment of the underside of wafers or circuit boards.

In a further development, the device according to the invention comprises a plurality of wetting stations or wetting rolls arranged one after another in the transporting direction, in each case one or more transport rollers of the roller transport system being arranged between said wetting stations or wetting rolls. In this case, at least two wetting rolls have said height offset with respect to the section, adjoining the supply side, of the roller transport system. In this way, the increase, achieved by the height offset, in the wetting of the front region of the substrate can be brought about a number of times in succession.

In a further configuration of such a device having a plurality of wetting rolls, at least two successive wetting rolls and the intermediate section of the roller transport system having one or more transport rollers are located at the same height. The device configured in this way thus combines one or more process sections which have a wetting roll height offset for the increased wetting of the substrate front edge, with one or more process sections in which the wetting rolls are located in a conventional manner at the same height as the section, adjoining on the supply side, of the roller transport system. Height-offset wetting rolls and wetting rolls without a height offset can be arranged in any desired sequence in the substrate transport direction in such a device, in order to achieve a respectively desired wetting or treatment effect for the substrates.

In a further configuration, in such a device, more wetting stations having height-offset wetting rolls are arranged within an inlet-side half of a treatment path from a furthest forward to a last wetting station than within an outlet-side half of the treatment path. Tests show that, for example for the etching treatment of the underside or the edge isolation of solar cell wafers, this can result in advantageous etching or edge-isolation results.

In another configuration, in a device according to the invention having a plurality of wetting rolls, the distance between in each case two successive height-offset wetting rolls is greater than the length of the substrates to be treated in the transporting direction. This ensures that a substrate to be treated has completely passed a preceding height-offset wetting roll before it reaches a next height-offset wetting roll. This avoids the front side of the substrate being raised by a next height-offset wetting roll, while it is still resting further back on a preceding wetting roll. Furthermore, this avoids the situation in which the substrate, on reaching the rear height-offset wetting roll, is still in a non-horizontal position in which it is inclined upwardly towards the front, this position being brought about by the preceding height-offset wetting roll. In this inclined position, the front edge of the substrate would possibly not butt against the next height-offset wetting roll at all.

In a further development of the invention, the wetting roll height offset with respect to the section, adjoining on the supply side, of the roller transport system is between 0.1 mm and 1.5 mm. Alternatively or in addition, this height offset is greater than a thickness of the flat substrates to be treated. Tests show that this quantitative selection of the wetting roll height offset results in very good, uniform wetting or treatment results, in particular also for the case of etching the underside of solar cell wafers or silicon wafers.

Advantageous exemplary embodiments of the invention are illustrated in the drawings and described in the following text. In the drawings:

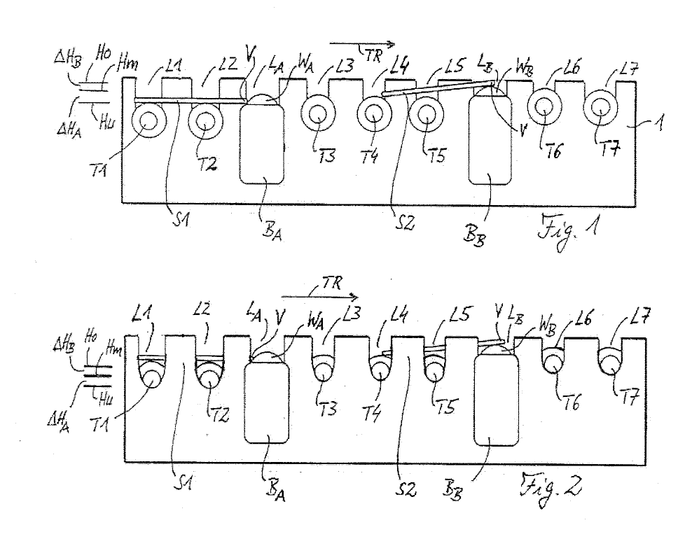

FIG. 1 shows a schematic longitudinal sectional view through a part of a device for the wet treatment of substrates, having a plurality of wetting stations,

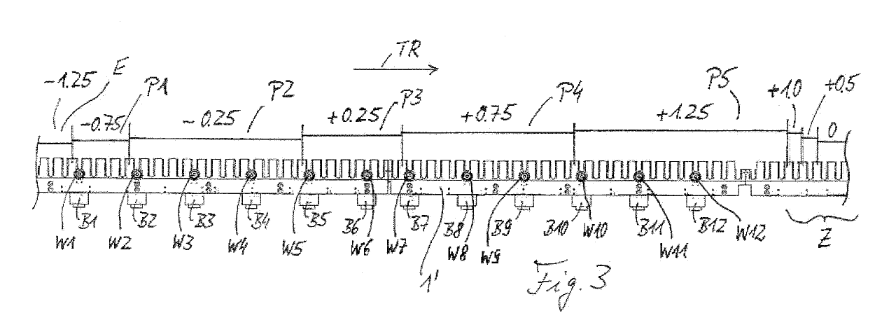

FIG. 2 shows a schematic side view of the device part from FIG. 1, and

FIG. 3 shows a schematic side view of a further device for the wet treatment of substrates, having a plurality of wetting stations.

FIGS. 1 and 2 show a part, of interest here, of a device for the wet treatment of flat substrates S1, S2 by wetting the underside with fluid using a plurality of wetting stations B_{A}, B_{B}. A roller transport system serves to move the substrates S1, S2 to be treated one after another in a continuous process in a horizontal transporting direction TR to various process stations to which the two wetting stations B_{A}, B_{B} shown belong. Depending on requirements, further process stations for carrying out further treatment steps for the substrates S1, S2 can be provided in a conventional manner upstream and/or downstream of the wetting stations B_{A}, B_{B}. The substrates S1, S2 may be silicon wafers for the production of solar cells, or alternatively other flat substrates, such as circuit boards and the like, which are conventionally treated in such continuous plants and are intended to be subjected to a fluid treatment, for example an etching treatment or a rinse treatment.

The roller transport system contains a plurality of transport rollers T1, T2, . . . , T7, W_{A}, W_{B}, which are arranged one after another in a spaced apart manner in the transporting direction TR and by way of which the substrates S1, S2 resting thereon can be moved in the transporting direction TR. To this end, the transport rollers T1 to T7, W_{A}, W_{B} are arranged with a horizontal longitudinal axis extending transversely to the transporting direction TR and are mounted on both sides in a respective roller longitudinal member, it being possible to see one roller longitudinal member 1 from the inside and from the outside, respectively, in the views in FIGS. 1 and 2. The respective roller longitudinal member 1 is provided from its top side with U-shaped incisions or recesses L1, . . . , L7 into which a bearing insert is introduced which carries a bearing for the respective transport rollers T1 to T7. Such a transport roller mounting is known per se for example from the abovementioned DE 101 28 386 A1, to which reference may be made for further details.

The respective wetting station B_{A}, B_{B} contains a treatment fluid bath and, in the example shown, an individual wetting roll W_{A}, W_{B} which is arranged in a conventional manner, not shown in more detail here, above the treatment fluid bath such that it dips into the bath with a bottom part of its circumference. The wetting rolls W_{A}, W_{B} belong, together with the rest of the transport rollers T1 to T7 that do not have a wetting function, to the transport rollers of the roller transport system and, like the transport rollers T1 to T7, are arranged with a horizontal longitudinal axis extending transversely to the transporting direction TR, and are likewise mounted on the respective roller longitudinal member 1 at their ends. For this purpose, the roller longitudinal members 1 again have suitable bearing inserts in recesses L_{A}, L_{B}. Both the non-wetting transport rollers T1 to T7 and the wetting rolls W_{A}, W_{B} are set in rotation in a conventional manner by associated drive means. The rotation of the transport rollers T1 to T7 brings about substrate transport in the transporting direction TR, and the rotation of the wetting rolls W_{A}, W_{B} additionally ensures that the treatment fluid is carried upwardly out of the bath on the circumference of the wetting rolls W_{A}, W_{B} and wets the underside of the substrates S1, S2 moved thereover, wherein the wetting rolls W_{A}, W_{B} make contact at their top side with the substrate underside, for example roll along the latter. Such wetting stations are known per se to a person skilled in the art, for example in the form of corresponding products by the applicant, and are described in the applicant's abovementioned earlier German Patent Application 10 2011 081 981, to which reference may be made for further details.

Characteristically, in the device shown in FIGS. 1 and 2, the wetting rolls W_{A}, W_{B} are arranged in an upwardly height-offset manner with respect to a section, in each case adjoining on the supply side, of the roller transport system. Specifically, a section of the roller transport system, said section being located upstream of the wetting station B_{A} shown first and comprising the two transport rollers T1, T2 shown furthest forward, is located at a height Hu which is at a level Hm that is lower by a height offset ΔH_{A} than the height of the wetting roll W_{A}, i.e. Hm=Hu+ΔH_{A}. The term height should be understood as meaning in each case the level of the top side of the transport rollers T1 to T7 or wetting rolls W_{A}, W_{B}, i.e. the level of the rollers T1 to T7 or rolls W_{A}, W_{B} at the highest point of their rotating circumferential/lateral surface. This height consequently corresponds in each case to the height of the underside of the substrates S1, S2 resting on the rollers T1 to T7 or rolls W_{A}, W_{B}.

A central section of the roller transport system, said section containing the three transport rollers T3, T4, T5 between the two wetting stations B_{A}, B_{B}, is located at the same height as the wetting roll W_{A} of the wetting station B_{A} located upstream thereof, i.e. the transport rollers T3, T4 and T5 have the same top-side level Hm as the wetting roll W_{A}. By contrast, the wetting roll W_{B} of the second wetting station B_{B} following this central section of the roller transport system has in turn a predeterminable upward height offset ΔH_{B}, i.e. the top-side level of the wetting roll W_{B} is located at a height Ho=Hm+ΔH_{B}. A third section of the roller transport system, said third section adjoining the second wetting station B_{B} in the transporting direction TR and comprising the transport rollers T6 and T7, is at the same height Ho as the wetting roll W_{B} located upstream thereof.

The height offset ΔH_{A}, ΔH_{B} according to the invention of a respective wetting roll W_{A}, W_{B} with respect to the section, located directly upstream, i.e. adjoining on the supply side, of the roller transport system has the result that a substrate S1, S2 moved up to the wetting roll W_{A}, W_{B} in question runs or butts by way of a front edge region V against the rotating wetting roll W_{A}, W_{B} and is then carried along by the latter to the increased level. FIGS. 1 and 2 illustrate a situation in which the rear substrate S1 is just butting with its front edge region V against the first wetting roll W_{A}, while the front edge region V of the front substrate S2 has already been raised by the second wetting roll W_{B} to the higher level Ho thereof.

It goes without saying that the height offset ΔH_{A}, ΔH_{B} of the respective wetting roll W_{A}, W_{B} with respect to the section, adjoining on the supply side, of the roller transport system, is always selected to be smaller, preferably much smaller, than a radius of the wetting roll W_{A}, W_{B}, so that the introduced substrate comes into contact with the wetting roll W_{A}, W_{B} in a circumferential region of the roll that is close to the top side, and can be carried along and raised without problems by said wetting roll W_{A}, W_{B}. Preferably, the point at which the front edge of the substrate strikes the wetting roll W_{A}, W_{B} is at an angle of less than 60°, preferably less than 45°, to the vertical, measured from the midpoint of the circular roll cross section. The roll height offset ΔH_{A}, ΔH_{B} then remains sufficiently smaller than the wetting roll radius. In advantageous realizations, the respective height offset ΔH_{A}, ΔH_{B} is between 0.1 mm and 1.5 mm, wherein the two values ΔH_{A} and ΔH_{B} can be selected to be identical or different. The height offset ΔH_{A}, ΔH_{B} can additionally be coordinated with the thickness of the flat substrates S1, S2 to be treated, for example such that it is greater than the thickness of the substrates. In order to make the height offset clearly discernible, it is illustrated in an exaggerated manner in FIGS. 1 and 2, which are not drawn to scale.

In the example shown in FIGS. 1 and 2, the height for the transport rollers T1 to T7 and the wetting rolls W_{A}, W_{B} is set individually by the depth of the associated vertical recesses L1 to L7 in the roller longitudinal members 1. This means that the depth of the recesses L3, L4, L5, L_{A} for the central transport rollers T3, T4, T5 and the first wetting roll W_{A} is selected to be smaller by the height offset ΔH_{A} than the depth of the recesses L1, L2 for the two transport rollers T1, T2 on the inlet side. Similarly, the depth of the recesses L_{B}, L6, L7 of the second wetting roll W_{B} and the two last transport rollers T6, T7 is selected to be smaller by the height offset ΔH_{B} than the depth of the recesses L3, L4, L5 for the transport rollers T3, T4, T5 of the section, adjoining upstream, of the roller transport system. Identically configured bearing inserts can be introduced into the recesses L1 to L7, L_{A}, L_{B} having different depths. In FIG. 2, the different depths of the recesses L1 to L7, L_{A}, L_{B} for the bearing inserts for the provision of the respective height offset are indicated in an illustration which is not to scale and reproduces the size of the height offset in an exaggerated manner. In an alternative embodiment, all of the recesses are introduced with the same depth into the roller longitudinal member, and differently configured bearing inserts having a corresponding height offset of the mounting level provided thereby are used in order to realize the height offset for the transport rollers T1 to T7 and the wetting rolls W_{A}, W_{B}.

As a result of the front edge region V of the substrates S1, S2 to be wetted on the underside butting or running against the wetting roll W_{A}, W_{B} which is height offset upwardly with respect to the supply-side transporting level, with the resulting carrying along and raising of this front substrate region V by the rotating wetting roll W_{A}, W_{B}, the degree of wetting of the substrate S1, S2 with the treatment fluid can be intensified or homogenized. It is ensured that the front edge region V of the substrate S1, S2 comes directly into contact with the wetting roll W_{A}, W_{B} and remains in contact therewith over a particular movement path, specifically from the point at which it butts against the wetting roll W_{A}, W_{B} until it reaches the highest point, i.e. the reversal point, of the wetting roll W_{A}, W_{B}.

Tests have shown that in this way too little wetting of the underside of the substrate in the front edge region V can be counteracted surprisingly well. A comparatively homogeneous wetting result over the entire underside of the substrate can thus be achieved. Specifically, in the application for the wet chemical etching of the underside of silicon wafers for the purpose of edge isolation, it is possible for uniform edge isolation to be brought about both in the front edge region V and in the rear edge region opposite thereto in the transporting direction TR. The abovementioned use of a rotation station for rotating the wafers, in order to transpose the front and rear edge region in the course of their process path and in this way to ensure a more uniform etching result in the front and rear edge region, can be omitted by the use of the device according to the invention.

The slight inclined position, brought about by the raising of the front edge region, of the treated flat substrates on crossing over a respective, upwardly height-offset wetting roll has a further advantage specifically in the case of the wet etching of the underside of silicon wafers. Frequently, a fluid mask, for example a water mask, is applied to the substrate top side in order to protect this side from the influence of the etching fluid to be applied to the underside. The slight raising of the substrates after reaching a height-offset wetting roll reliably prevents a part of the fluid mask on the top side from passing onto this wetting roll and diluting the treatment fluid in an undesired manner there. Instead, the fluid mask on the top side can run off in the direction of the rear edge of the substrate.

Although FIGS. 1 and 2 show a device part having two wetting stations B_{A}, B_{B} with height-offset wetting rolls W_{A}, W_{B}, it goes without saying that the invention also includes devices which have only one wetting station with a wetting roll height offset, or more than two such wetting stations. In the example shown, each wetting station B_{A}, B_{B} contains an individual wetting roll W_{A}, W_{B}. It goes without saying that, in alternative embodiments of the invention, the respective wetting station may also have a plurality of wetting rolls, which dip for example into a common treatment fluid bath, wherein all or only a part, which is selectable as desired, of the plurality of wetting rolls may be arranged with a height offset.

Preferably, the distance between two successive wetting rolls with a height offset is greater than a length of the substrates to be treated in the transporting direction TR. This ensures that, after leaving the front wetting roll, the substrates initially assume their precisely horizontal position on the transport roller or rollers between the two height-offset wetting rolls again, before they reach the subsequent wetting roll with a height offset.

FIG. 3 schematically shows a device for the wet treatment of substrates, as can be used for example for wet etching the underside of solar cell silicon wafers. To this end, in its process section, which is of interest here and illustrated in FIG. 3, the device has twelve wetting stations B1 to B12 of the kind of the wetting stations B_{A}, B_{B} explained above with reference to FIGS. 1 and 2, each having a wetting roll W1 to W12, and a roller transport system of the kind of the roller transport system explained above with reference to FIGS. 1 and 2, wherein the non-wetting transport rollers have been omitted in FIG. 3 for the sake of clarity. The transport rollers, including the wetting rolls W1 to W12, are, just as explained above for the devices in FIGS. 1 and 2, mounted on lateral roller longitudinal members, of which one roller longitudinal member 1′ can be seen in the view in FIG. 3. Specifically, the roller longitudinal members 1′ are, for this purpose, provided again with receptacles or incisions which are introduced vertically from their top side and into which suitable bearing inserts for the transport rollers have been introduced. As explained above with respect to the exemplary embodiment in FIGS. 1 and 2, the incisions in the roller longitudinal members 1′ and the inserts introduced into said incisions are selected, here too, such that the transport roller in each case mounted thereon assumes the desired height.

The process part, shown in FIG. 3, of the device for the wet treatment or wet etching of the underside of flat substrates has a plurality of treatment sections P1 to P5 located one after another, said treatment sections P1 to P5 each containing one or more of the wetting stations B1 to B12, the wetting rolls of which are located at the same height and are raised with respect to the wetting roll height of the respectively preceding treatment section. In FIG. 3, the different heights are represented by corresponding numerical data for the associated treatment sections P1 to P5 and for the adjoining sections E, Z of the roller transport system.

Specifically, an inlet-side section E of the roller transport system is followed by a first treatment section P1 which contains the first wetting station B1. Compared with a predetermined zero reference height, the transport rollers in the inlet-side section E are at a height lowered by −1.25 mm. By contrast, the height of the directly adjoining wetting roll W1 of the first wetting station B1 and also of the adjoining transport rollers in the first treatment section P1 is raised by 0.5 mm, i.e. it is located at −0.75 mm. This corresponds to the height offset ΔH_{A} in the example of FIGS. 1 and 2. The first treatment section P1 is followed by a second treatment section P2 which comprises the next three wetting stations B2, B3, B4 and the height of which for the wetting rolls W2, W3, W4 and the respectively following transport rollers is again upwardly offset by 0.5 mm with respect to the height of the first treatment section P1, i.e. is located at −0.25 mm. Thus the height offset of the wetting rolls W2 of the second treatment section P2 relative to the transport roller section, adjoining on the supply side, having the transport rollers of the first treatment section P1 is again present at the furthest forward wetting station B2 of the second treatment section P2. This corresponds to the height offset ΔH_{B} of the second wetting station B_{B} in the example of FIGS. 1 and 2.

The second treatment section P2 is followed in the transporting direction TR by a third treatment section P3 which includes the next two wetting stations B5, B6 and the height of which is in turn upwardly offset by 0.5 mm with respect to that of the preceding treatment section P2, i.e. is located at +0.25 mm. This produces in turn the height offset for the wetting roll W5 of the front wetting station B5 with respect to the transport rollers, located upstream, of the treatment section P2. In an analogous manner, the third treatment section P3 is followed by a fourth treatment section P4 having the next three wetting stations B7, B8, B9 and this is followed by a fifth treatment section P5 having the last three wetting stations B10, B11, B12, each in turn having an upward height offset of 0.5 mm with respect to the preceding treatment section. The last treatment section P5 is followed by an output-side section Z of the roller transport system, in which the substrate transporting height is reduced in a stepped manner in three steps made of in each case at least one transport roller from the raised level at +1.25 mm of the last treatment section P5 to the zero reference level of 0 mm via the intermediate levels at +1.0 mm and +0.5 mm. The section Z, on the outlet side in FIG. 3, of the roller transport system may be for example a supply section of a subsequent rinsing module, in which any treatment fluid that remains on the substrates is rinsed off.

This produces the following process sequence for the substrates treated with the plant parts in FIG. 3. In the inlet-side section E of the roller transport system, the substrates are guided at the lowered height of −1.25 mm up to the first wetting roll W1, which is upwardly offset by 0.5 mm compared therewith, and are wetted to an increased extent in the front edge region of the substrate by said wetting roll W1 on account of the height offset, as explained above. The substrate travels over the wetting roll W1 and its underside is wetted thereby for the first time with the treatment fluid. Subsequently, it passes to the second wetting roll W2, which is in turn height offset, and its underside is wetted for a second time there, again with increased wetting of the front edge on account of the height offset. Subsequently, the substrate travels in the usual manner over the next two wetting rolls W3 and W4, in order to be wetted for a third and fourth time in each case in a conventional manner without a wetting roll height offset. Then, the substrate passes to the fifth wetting roll W5, which is in turn height offset, where it is subjected to increased wetting of the front edge for the third time, in order subsequently to be wetted a further time without increased wetting of the front edge by the wetting roll W6, which is not height offset with respect to the directly preceding transport rollers. From there, the substrate passes to the seventh wetting roll W7, which is in turn height offset, and is wetted there for a fourth time with increased wetting of the front edge. This is followed by two wetting operations by the next wetting rolls W8 and W9, which are not height offset. Then, the substrate passes to the last height-offset wetting roll W10 at the start of the fifth treatment section P5 and undergoes wetting with increased wetting of the front edge for the last time there. This is followed by two more normal wetting operations without increased wetting of the front edge by the wetting rolls W11 and W12. This concludes the wetting treatment and the substrate passes to the outlet side Z of the roller transport system via the two intermediate stages from the increased level at +1.25 mm to the reference level of 0 mm.

As can be seen from FIG. 3 and the above statements, more wetting stations having a height-offset wetting roll are provided in a first half of the treatment path extending from the first wetting station B1 to the last wetting station B12, said first half being at the front in the transporting direction TR, than within the second half on the outlet side. Specifically, three wetting stations B1, B2, B5 having a height-offset wetting roll W1, W2, W5 are provided in the first half comprising the first three treatment sections P1, P2, P3 and only two wetting stations B7, B10 having a height-offset wetting roll W7, W10 are provided in the half on the outlet side. This favours early increased wetting of the front edge region of the substrate during the treatment period which extends temporally for the respective substrate from reaching the first wetting roll W1 until leaving the last wetting roll W12. It goes without saying that the sequence of wetting stations with a height-offset wetting roll and those with no height-offset wetting roll can be set suitably as desired in a manner coordinated with the respective application. The same applies to the amount of the particular height offset. In the example of FIG. 3, the height offset is always 0.5 mm, but in alternative embodiments of the invention it may have any other desired value, for example in the range between 0.1 mm and 1.5 mm and, if required, it may also be set differently, in particular for different wetting stations along the treatment path.

1. A device for the wet treatment of flat substrates by wetting the underside with fluid, comprising:
at least one wetting station with at least one wetting roll for wetting the underside of the substrates to be treated and moved in a transporting direction over the treatment roller with fluid, and
a roller transport system having a plurality of transport rollers, arranged one after another in a spaced apart manner in the transporting direction, including the at least one wetting roll, for transporting the substrates to be treated and resting on the transport rollers in the transporting direction,
wherein the wetting roll is arranged at a height which is higher by a predetermined height offset than a height which is defined by a section, adjoining the supply side of the wetting roll, of the roller transport system.

2. The device according to claim 1, wherein the at least one wetting station comprises a plurality of wetting stations or wetting rolls arranged one after another in the transporting direction, in each case one or more transport rollers of the roller transport system being arranged between said wetting stations or wetting rolls, wherein at least two of the wetting rolls are arranged in each case at a height which is higher by a predetermined amount than the height of the section, adjoining the supply side of said wetting rolls, of the roller transport system.

3. The device according to claim 2, wherein at least two successive wetting rolls are arranged at one and the same height which is the same as a height of an intermediate section of the roller transport system.

4. The device according to claim 3, wherein more height-offset wetting rolls are arranged within an inlet-side half of a treatment path from a furthest forward to a last wetting roll than within an outlet-side half of the treatment path.

5. The device according to claim 2, wherein the distance between in each case two successive height-offset wetting rolls is greater than the length of the substrates to be treated in the transporting direction.

6. The device according to claim 1, wherein the wetting roll height offset is at least one of between 0.1 min and 1.5 mm and/or greater than a thickness of the flat substrates.

7. Use of a device according to claim 1 for the wet-chemical etching of the underside or the rinse treatment of the underside of silicon wafers or circuit boards.
